(19) United States
(12) Patent Application Publication
(10) Pub. No.: US 2005/0140288 A1
(43) Pub. Date: Jun. 30, 2005

(54) Display device and method and apparatus for manufacturing display device

(76) Inventor: Koji Suzuki, Haguri-gun (JP)

Correspondence Address: CANTOR COLBURN, LLP, 55 GRIFFIN ROAD SOUTH, BLOOMFIELD, CT, 06002, US

(21) Appl. No.: 11/022,441

(22) Filed: Dec. 22, 2004

(30) Foreign Application Priority Data
Dec. 26, 2003 (JP) 2003-435819

(51) Int. Cl. H01J 1/62; H01J 63/04

(52) U.S. Cl. 313/506

(57) ABSTRACT

A display device having a plurality of pixels and which realizes a color display using emitted light of at least two wavelengths, wherein each pixel has a microresonator structure formed between a lower reflective film formed on a side near a substrate and an upper reflective film formed above the lower reflective film with an organic light emitting element layer therebetween. The lower reflective film is formed by a metal thin film and a conductive resonator spacer layer which functions as a first electrode is provided between the lower reflective layer and the organic light emitting element layer. The conductive resonator spacer layer is a transparent conductive metal oxide layer such as ITO and is formed to different thicknesses for pixels of different light emission wavelengths by forming the conductive resonator spacer layer in different film formation chambers, for example. Light obtained in the organic light emitting element layer is intensified by the microresonator structure having an optical length adjusted by the conductive resonator spacer layer and is emitted to the outside.

### CROSS-REFERENCE TO RELATED APPLICATIONS

The entire disclosure of Japanese Patent Application No. 2003-435819 including specification, claims, drawings and abstract is incorporated herein by reference in its entirety.

### BACKGROUND OF THE INVENTION

1. Field of the Invention

The present invention relates to a display device and, in particular, to a color display device having a microresonator (microcavity) structure.

2. Description of the Related Art

In recent years, flat panel displays (FPD) having a thin thickness and which allow reduction in size have attracted much attention. Of various FPDs, liquid crystal display devices are used in various devices. Currently, there is intense research and development into light emitting devices (display devices and light sources) in which a self-emitting electroluminescence (hereinafter referred to simply as “EL”) elements, in particular, organic EL display devices which can emit light at various light emission colors and at a high brightness depending on organic compound materials to be used.

Because an organic EL display device differs from a liquid crystal display device which employs a system in which transmissivity of light from a backlight is controlled by a liquid crystal panel which is placed as a light valve in front of the backlight and the organic EL display device is self-emissive as described above, fundamentally, the usage efficiency of light, that is, the extraction efficiency of light to the outside is high, and consequently, light emission of high brightness can be achieved by the organic EL display device.

However, the light emission brightness of currently proposed organic EL elements is not sufficient. In addition, there is a problem in that, when the supplied current to the organic layer is increased in order to improve the light emission brightness, deterioration of the organic layer is accelerated.

As a method for solving these problems, a method can be considered in which intensity of light at a certain wavelength is intensified in an EL display device by employing a microresonator, as described in Japanese Patent Laid-Open Publication No. Hei 6-275381 and in Takahiro Nakayama and Atsushi Tsunoda, “Elements having Optical Cavity Structure”, Molecular Electronics and Bioelectronics Division of Japan Society of Applied Physics, Third Convention of 1993, p. 135-p. 143.

When a microcavity (microresonator) structure is to be employed in an organic EL element, a metal electrode (for example, cathode) which functions as a reflective mirror is provided as an electrode which is on a rear side of the element, a semi-transmissive mirror is provided on a front surface (on the side of the substrate) of the element, and the optical length L between the semi-transmissive mirror and the metal electrode is designed such that the following equation (1) is satisfied.
2nL=(m+½)λ (1)
wherein λ is the light emission wavelength. With this structure, it is possible to selectively intensify light at the wavelength λ and to emit the light to the outside. The variable n in equation (1) represents an index of refraction and the variable m represents an integer (0, 1, 2, 3, . . . ).

This relationship can be easily designed when an organic EL display device having a single wavelength as the emission wavelength, that is, a monochrome organic EL display device, is used, or when the display device is used as a surface light source.

However, when a full-color organic EL display device is to be manufactured, the wavelengths to be intensified within one display panel include, for example, 3 colors of R, G, and B. Therefore, light at different wavelengths must be intensified in different pixels. In order to do so, the optical lengths L between the semi-transmissive mirror and the metal electrode must be changed for each pixel depending on the wavelength of light to be emitted.

On the other hand, unlike a semiconductor device used in an integrated circuit or the like, in a display device, the display itself is viewed by a viewer. Therefore, no structure can be actually employed as a display device unless the structure can stably achieve a high display quality in all pixels.

Because of this, although, for example, theoretically, the cavity (resonator) structure as described above can be realized in a full color display device by setting the optical length in each pixel depending on the light emission wavelength, when the pixels are independently manufactured to achieve different thicknesses, the number of processes in the manufacturing is inevitably increased and the manufacturing processes become more complicated, which results in serious degradation of the quality and variation. In particular, because an organic EL display device currently has a problem with respect to the stability of the display quality, if a resonator structure is simply used, the yield is reduced when the display devices are mass-produced and the manufacturing cost is significantly increased. Therefore, application of the microresonator to an EL display device has been only researched and has not yet been commercialized.

### SUMMARY OF THE INVENTION

According to one aspect of the present invention, there is provided a display device comprising a plurality of pixels and which realizes a color display using emitted light of at least two wavelengths, wherein each of the plurality of pixels comprises a microresonator structure formed between a lower reflective film formed on a side near a substrate and an upper reflective film formed above the lower reflective film with an organic light emitting element layer therebetween, the lower reflective film is formed by a transflective metal thin film, a conductive resonator spacer layer which functions as an electrode for supplying charges to the organic light emitting element layer and having an individual pattern for each pixel is provided between the lower reflective film and the organic light emitting element layer, the conductive resonator spacer layer being a transparent conductive metal oxide layer and having a thickness which differs among pixels emitting light of different wavelengths, and light obtained in the organic light emitting element layer is intensified by the microresonator structure formed between the lower reflective film and the upper reflective film and is emitted to the outside through the conductive resonator spacer layer and the lower reflective film.

According to another aspect of the present invention, it is preferable that, in the display device, emitted light from each pixel is one of red, blue, and green, and the conductive resonator spacer layer is layered to different thicknesses for pixels of red, pixels of blue, and pixels of green.

According to another aspect of the present invention, there is provided a display device comprising a plurality of pixels and which realizes a color display using emitted light of at least two wavelengths, wherein each of the plurality of pixels comprises a microresonator structure formed between a lower reflective film formed on a side near a substrate and a transflective upper reflective film formed above the lower reflective film with an organic light emitting element layer therebetween, an optical length corresponding to a distance between the lower reflective film and the upper reflective film differing among pixels emitting light of different wavelengths, and light which is intensified by the microresonator structure is emitted to the outside through the upper reflective film.

According to another aspect of the present invention, it is preferable that, in the display device, a conductive resonator spacer layer which functions as an electrode for supplying charges to the organic light emitting element layer and having an individual pattern for each pixel is provided between the lower reflective film and the upper reflective film, and the conductive resonator spacer layer has a thickness which differs among pixels emitting light of different wavelengths.

According to another aspect of the present invention, it is preferable that, in the display device, the conductive resonator spacer layer is provided between the lower reflective film and the organic light emitting element layer and contains a conductive metal oxide.

According to another aspect of the present invention, it is preferable that, in the display device, the lower reflective film contains silver, gold, platinum, aluminum, or an alloy of any of these metals.

According to another aspect of the present invention, there is provided a manufacturing method of a display device which comprises a plurality of pixels and realizes a color display using emitted light of at least two wavelengths, and in which each pixel comprises a microresonator formed between a lower reflective film and an upper film formed above the lower reflective film with an organic light emitting element layer therebetween, the organic light emitting element layer having at least one layer; and an optical length corresponding to a distance between the lower reflective film and the upper reflective film of the microresonator differing among pixels corresponding to light emission colors; wherein the lower reflective film of each pixel is formed, and a plurality of conductive resonator spacer layers having different thicknesses among pixels of different colors of emitted light are sequentially formed on the lower reflective film and continuous with the lower reflective film in different film formation chambers.

According to another aspect of the present invention, it is preferable that, in the method for manufacturing a display device, the conductive resonate; spacer layer is an electrode layer which supplies charges to the organic light emitting element layer, and the conductive resonator spacer layer is formed in each of the film formation chambers by layering a conductive metal oxide to a predetermined thickness in an individual pattern for each pixel using a mask.

According to another aspect of the present invention, it is preferable that, in the method for manufacturing a display device, emitted light from each pixel is one of red, green, and blue, and the conductive resonator spacer layer is layered to different thicknesses for pixels of red, pixels of green, and pixels of blue.

According to another aspect of the present invention, it is preferable that, in the method for manufacturing a display device, the lower reflective film is a metal film containing silver, gold, platinum, aluminum, or an alloy of any of these metals, and a transparent conductive metal oxide layer is formed layer is formed as the conductive resonator spacer layer having a predetermined thickness sequentially after the metal film is formed.

According to another aspect of the present invention, there is provided an apparatus for manufacturing a display device in which each pixel comprises a microresonator formed between a lower reflective film and an upper reflective film formed above the lower reflective film with an organic light emitting element layer therebetween, an optical length corresponding to a distance between the lower reflective film and the upper reflective film of the microresonator differing among pixels corresponding to wavelengths of emitted light, and a color display is realized using emitted light of at least two wavelengths, the apparatus comprising a lower reflective film formation chamber in which the lower reflective film is formed, and a spacer film formation chamber in which a conductive resonator spacer layer is layered, the conductive resonator spacer layer being formed between the lower reflective film and the organic light emitting element layer for adjusting the optical length of the microresonator based on light emission wavelength of light emitted from the pixel, wherein a plurality of the spacer film formation chambers are provided corresponding to thicknesses of the conductive resonator spacer layer to be formed, and the lower reflective film formation chamber and the plurality of the spacer film formation chambers are connected to each other directly or through a transport chamber so that a substrate to be processed can be transported while a state of vacuum is maintained.

According to another aspect of the present invention, it is preferable that, in the spacer film formation chamber of the manufacturing apparatus of a display device, the conductive resonator spacer layer is formed on the lower reflective film in a vacuum atmosphere using a mask having an opening corresponding to a predetermined pixel region.

According to another aspect of the present invention, it is preferable that, in the manufacturing apparatus of a display device, the lower reflective film formation chamber is a film formation chamber in which a metal film containing silver, gold, platinum, aluminum, or an alloy of any of these metals is formed on the substrate to be processed, and in the spacer film formation chamber, an oxide of indium or tin or an indium tin oxide is layered to a predetermined thickness as the conductive resonator spacer layer on the substrate to be processed which is transported while a state of vacuum is maintained and onto which the metal film is formed.

According to the present invention, it is possible to easily and accurately form an optical microresonator (microcavity) in each pixel of a display device corresponding to the light emission wavelength.

### BRIEF DESCRIPTION OF THE DRAWINGS

A Preferred embodiment of the present invention will be described in detail based on the following drawings, wherein:

FIG. 1 is a diagram schematically showing a cross sectional structure of a display device having a microresonator structure according to a preferred embodiment of the present invention;

FIG. 2 is a diagram schematically showing another cross sectional structure of a display device having a microresonator structure according to a preferred embodiment of the present invention;

FIG. 3 is a diagram schematically showing a circuit of an active matrix organic EL display device according to a preferred embodiment of the present invention;

FIG. 4 is a diagram showing a portion of an apparatus for manufacturing a display device having a microresonator structure according to a preferred embodiment of the present invention; and

FIG. 5 is a diagram showing another configuration of an apparatus for manufacturing a display device having a microresonator structure according to a preferred embodiment of the present invention.

### DESCRIPTION OF PREFERRED EMBODIMENT

A preferred embodiment (hereinafter, referred to simply as “embodiment”) of the present invention will now be described referring to the drawings.

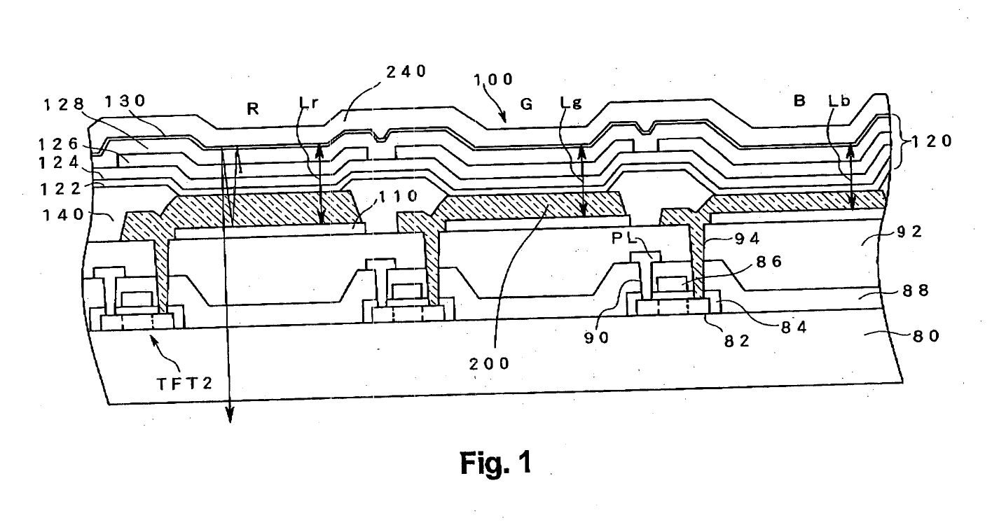

FIG. 1 is a diagram schematically showing a cross sectional structure of a display device having a microresonator (microcavity) structure according to a preferred embodiment of the present invention. The display device is a light emitting display device having a self-emissive display element in each pixel. The present invention will be described exemplifying an organic EL display device in which an organic EL element is used as the display element.

An organic EL element 100 has a layered structure having an organic light emitting element layer 120 which at least includes an organic compound, in particular, an organic light emitting material, between a first electrode 200 and a second electrode 240. The organic EL element 100 takes advantage of a principle that electrons are injected from an anode to the organic layer and holes are injected from a cathode to the organic layer, the injected electrons and holes recombine within the organic layer, the organic light emitting material is excited by the obtained recombination energy, and light is emitted when the organic light emitting material returns to its ground state.

A conductive metal oxide material such as, for example, ITO (Indium Tin Oxide) or IZO (Indium Zinc Oxide) is used as the first electrode 200 and Al or an alloy of Al which functions as an upper reflective film is used as the second electrode 240. A lower reflective film 110 is provided below the first electrode 200 for forming a microresonator structure between the upper reflective film and the lower reflective film.

When a bottom emission type display device is to be realized in which light obtained in the organic light emitting element layer 120 is emitted to the outside through the transparent first electrode 200 and the substrate 80, the lower reflective film 110 must be formed in a semi-transmissive manner which can partially allow light from the light emitting element layer 120 to transmit. As the lower reflective film 110, it is possible to employ any of Ag, Au, Pt, and Al or an alloy film thereof. The lower reflective film 110 is formed to a thickness which allows light to transmit or in a pattern having an opening such as a mesh shape and a lattice shape.

The organic light emitting element layer 120 has a light emitting layer which at least contains an organic light emitting molecule and may be formed in a single-layer structure or a layered structure of a plurality of layers such as 2, 3, and 4 layers, depending on the material. In the configuration of FIG. 1, the organic light emitting element layer 120 has a structure in which a hole injection layer 122, a hole transport layer 124, a light emitting layer 126, an electron transport layer 128, and an electron injection layer 130 are layered in this order from the side near the first electrode 200 which functions as the anode through continuous film formation of vacuum evaporation or the like. Moreover, the second electrode 240 which functions as the cathode in this configuration is formed on the electron injection layer 130 continuous from the organic light emitting element layer 120 through vacuum evaporation similar to the organic light emitting element layer 120.

The emitted light of the organic EL element depends on the organic light emitting molecule. In the case of a color display device having colors of R, G, and B, it is possible to form the light emitting layers 126 in individual patterns for each pixel and use different light emitting materials for R, G, and B. In this case, the light emitting layers 126 are set in patterns separate for R, G, and B pixels in order to at least prevent mixture of colors, and are formed in separate steps for R, G, and B. In the present embodiment, a light emitting material common to all pixels is used as the light emitting layer 126 and the same white light emitting layer is employed in all pixels, although the structure of the present embodiment is not limited to this configuration. More specifically, a layered structure of light emitting layers of orange and blue which are complementary colors is employed as the light emitting layer 126 and light emission of white color is realized by addition of colors.

When a white color light emitting EL element is employed in all pixels, all layers in t he organic light emitting element layer 120 can he formed common to all pixels. However, in order to more reliably control light emission for each pixel to increase the contrast, it is also possible to employ an individual pattern for each pixel. By forming the film using a mask (for example, through vacuum evaporation), the white color light emitting layer 126 can be formed in an individual pattern for each pixel simultaneous with the formation of the light emitting layer 126. In the configuration of FIG. 1, the same white color light emitting layer 126 is formed in an individual pattern for each pixel. The other layers, that is, the hole injection layer 122, the hole transport layer 124, the electron transport layer 128, and the electron injection layer 130, are formed common to all pixels (these layers may also be formed in an individual pattern in desired sizes using a mask) and the second electrode 240 is also formed common to all pixels.

The organic light emitting element layer 120 has a function to transport holes or electrons, but has a high resistance. Thus, charges are injected to the organic light emitting element layer 120 only in a region in which the first electrode 200 and the second electrode 240 directly oppose each other with the organic light emitting element layer 120 therebetween and the light emitting region of the organic EL element 100 corresponds to this region in which the first electrode 200 and the second electrode 240 oppose each other. More specifically, because end regions of the first electrode 200 are covered by a planarizing insulating layer 140, an opening region in the planarizing insulating layer 140 above the first electrode 200 becomes the light emitting region of the organic EL element 100.

The microresonator (microcavity) structure of the present embodiment is formed in the region in which the transparent first electrode 200 and the second electrode 240 oppose each other with the organic light emitting element layer 120 therebetween, between the lower reflective film 100 below the first electrode 200 and the second electrode 240 which also functions as the upper reflective film. An optical length L of the microresonator is actually a length corresponding to an interlayer distance (thickness) between the lower reflective film 110 and the upper reflective film 240 and a penetration distance of light in the lower reflective film 110 and the upper reflective film 240. Optical lengths L (Lr, Lg, and Lb) described by the above-described equation (1) are formed in the pixels of R, G, and B corresponding to the wavelengths λ of R, G, and B (λr, λg, and λb). Here, because a metal material is used for the lower reflective film 110 and the upper reflective film 290, the penetration distance of light in these films is approximately zero. Because of this, with the white light emitted from the white light emitting layers 126 having the same structure, for example, only the light of wavelength of R, G, or B is resonated and intensified corresponding to the optical lengths L in each pixel and is emitted to the outside. In a configuration in which the emission colors of the light emitting layers 126 are R, G, and B corresponding to the R, G, and B pixels, the light of the wavelength λ corresponding to the optical length L of the microresonator formed in the pixels is intensified among the wavelength components and is emitted to the outside. In addition, because the directionality of the emitted light, in particular, the directionality toward the front direction of view of the display, is improved with the microresonator structure, the light emission brightness at the front position can be increased.

In the present embodiment, in order to vary the optical lengths L among the pixels based on the light emission wavelength λ, of the first electrode 200 present between the lower reflective film 110 and the upper reflective film 240 and the organic light emitting element layer 120, a conductive resonator (cavity) space layer is used as the first electrode 200 to adjust the thickness.

When the first electrode 200 is to be formed individually for each pixel, by using masks having openings only in the target pixel regions in different film formation chambers and setting the film formation periods corresponding to the thicknesses, it is possible to automatically form the first electrode 200 for the pixels having different thicknesses corresponding to the film formation chambers, that is, corresponding to the light emission wavelengths, The first electrode 200 made of a transparent conductive metal material such as ITO as described above may be formed, for example, through sputtering or, alternatively, maybe formed through vacuum evaporation. In either case, by applying the film formation process with a mask placed in front of the material source of the substrate to be processed during the film formation, it is possible to obtain the first electrode 200 having the desired thickness as the resonator spacer layer. In addition, the first electrode 200 is formed continuously from the formation of the lower reflective film 110 formed below the first electrode 200 without exposure of the structure to the atmosphere (air) using a manufacturing apparatus which will be described below. With this configuration, it is possible to reliably prevent reduction in the reflectivity and reduction in degree of contact between the first electrode 200 and the lower reflective film 110 due to coverage of the surface of the lower reflective film 110 by a natural oxide film or adhesion of impurities at the interface between the lower reflective film 110 and the first electrode 200.

The microresonator according to the present embodiment is not limited to the bottom emission type structure as described above and may also be applied to a top emission type EL display device.

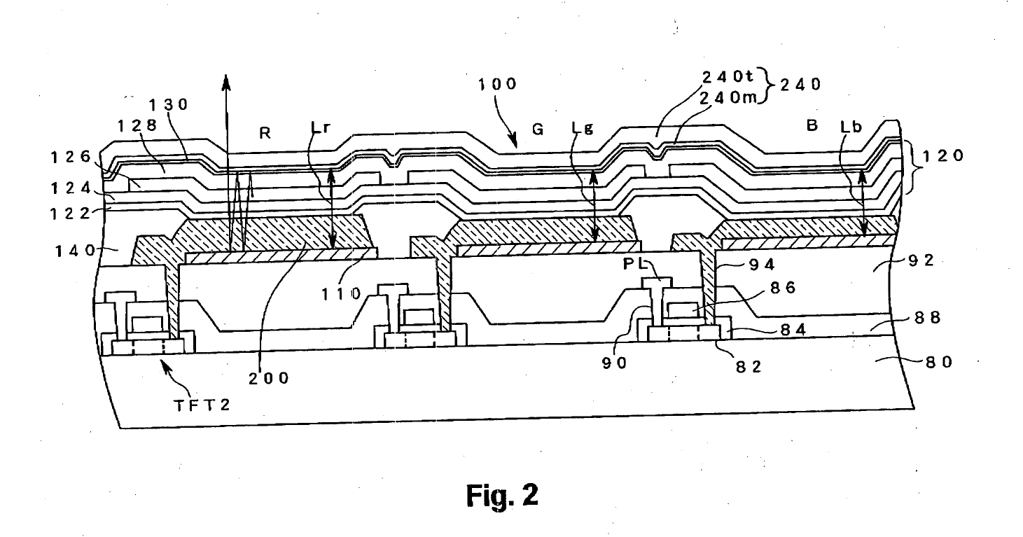

FIG. 2 shows a structure in which a microresonator structure is employed in a top emission type display device in which light obtained in the organic light emitting element layer 120 is emitted through the second electrode 240. In a top emission type structure, a light reflection film (mirror) having a reflectivity of approximately 100% is used as the lower reflective film 110, In this structure also, the lower reflective film 110 is formed to a sufficient thickness using the same material as that of the semi-transmissive (transflective) lower reflective film 110 as described above, or as a film without any opening.

The second electrode 240 must be optically transmissive, When the second electrode 240 functions as a cathode, a metal thin film 240m made of a material of a low work function such as Ag and Au for maintaining electron injecting characteristics is provided on a side near the interface with the organic light emitting element layer 120 to a thin thickness which allows light to transmit, or in a pattern having an opening such as a mesh shape or a lattice shape and a transparent conductive layer 240t made of ITO or the like is formed on the thin film 240m to form the second electrode 240. The upper reflective film for forming the microresonator with the lower reflective film 110 maybe realized using the semi-transmissive metal thin film 240, formed on the side of the second electrode 240 near the interface with the organic light emitting element layer 120.

In the present embodiment, a microresonator structure can be formed between the lower reflective film 110 and the upper reflective film 240 both in a bottom emission type display device and in the top emission type display device. In either case, the first electrode 200 is formed to different thicknesses for each light emission wavelength and is used as the conductive resonator spacer layer for adjusting the optical length L.

In the present embodiment, an active matrix organic EL display device can be employed in which a switching element is provided in each pixel and the organic EL element is individually controlled. The first electrode 200 is electrically connected to a corresponding switching element and is formed in an independent pattern for each pixel. With the first electrode 200 having an individual pattern for each pixel, even when the first electrode 200 is formed to thicknesses different for pixels of R, G, and B, it is possible to reliably and easily adjust the optical length L of the pixel without affecting the structure of pixels of other colors. In a passive matrix display device in which no switching element is provided in each pixel, a method for changing the thicknesses, of a plurality of the first electrodes 200 which are formed along one direction in a stripe pattern, line by line may be employed, as such a method allows easy manufacturing steps and is efficient for avoiding adhesion of impurities or the like to the surface of the first electrode 200.

In order to change the optical length L, it is also possible to change other conditions such as, for example, the thickness of the organic light emitting element layer 120 for the pixels of different light emission wavelengths. However, the layers formed common to all pixels among the layers in the organic light emitting element layer 120 are preferably simultaneously formed because such a configuration simplifies the manufacturing steps, and, moreover, it is very important to continuously form the films in the organic light emitting element layer 120 having a layered structure with a minimum number of steps and without breaking the state of vacuum in order to prevent deterioration as the organic layer of the organic EL element is known to deteriorate due to moisture, oxygen, and particles.

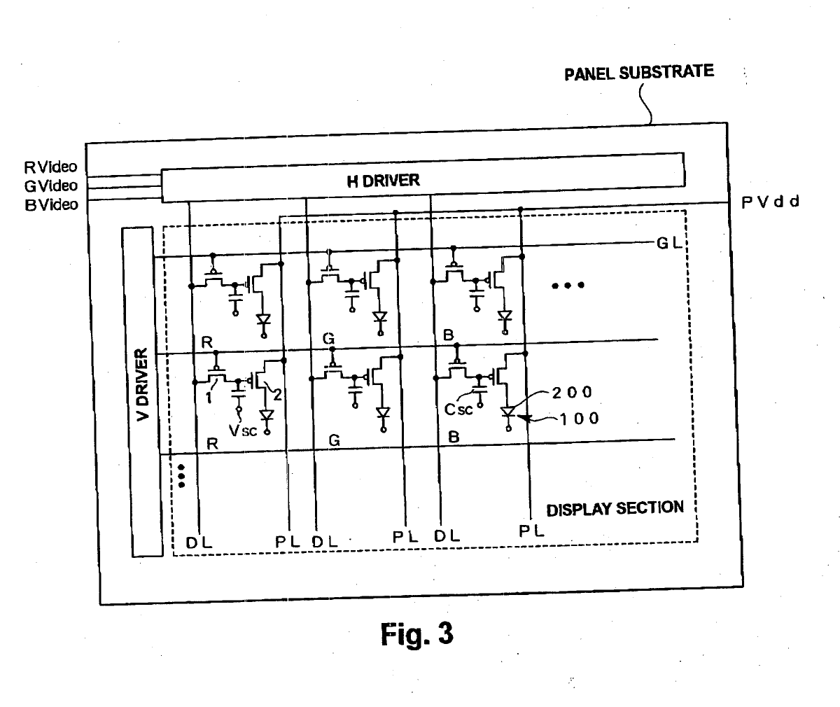

FIG. 3 is a diagram schematically showing a circuit structure of an active matrix organic EL display device according to the present embodiment. The circuit structure is not limited to that shown in FIG. 3, but, as an example configuration, each pixel comprises an organic EL element 100, a switching TFT 1, an EL driver TFT 2, and a storage capacitor Csc. A gate electrode of the TFT 1 is electrically connected to a gate line GL which extends along a horizontal direction of the display device and to which a scan signal is supplied. A source (or drain) of the TFT 1 is connected to a data line DL which extends along a vertical direction and to which a data signal is supplied. The storage capacitor Csc is connected to a drain (or source) of the switching TFT 1. When a scan signal is output and the TFT 1 is switched on, a voltage corresponding to a data signal voltage on the data line DL supplied via the source and drain of the TFT 1 is stored in the storage capacitor Csc until the next time the pixel is selected. The voltage stored in the storage capacitor Csc is applied to a gate electrode of the EL driver TFT 2 and the TFT 2 supplies a current from a power supply (PVdd) line PL to the first electrode 200 (in this configuration, anode) of the organic EL element 100 based on the voltage applied to the gate electrode of the TFT 2.

The TFT connected to the first electrode 200 of the organic EL element 100 in FIGS. 1 and 2 corresponds to the EL driver TFT 2 of FIG. 3 and the switching TFT 1 and the storage capacitor Csc are not shown in FIGS. 1 and 2. Both TFTs 1 and 2 use, as an active layer 82 formed on a glass substrate 80, polycrystalline silicon films which are simultaneously formed by polycrystallizing amorphous silicon through laser annealing. In addition, the elements necessary for the TFTs such as gate insulating films 84 and gate electrodes 86 are formed almost simultaneously and through the same processes. The semiconductor film 82 of the TFT 1 also functions as one of the electrodes of the storage capacitor Csc and the other electrode of the storage capacitor Csc is formed by a capacitor electrode line which opposes the first electrode of the storage capacitor Csc with the gate insulating film 84 therebetween, made of the same metal material as the gate electrode 86, and to which a predetermined capacitor voltage Vsc is applied.

The storage capacitor Csc, TFT 1, and TFT 2 are covered by an interlayer insulating film 88. A data line DL is connected to the source (or drain) of the TFT 1 through a contact hole 90 formed through the interlayer insulating film 88 and a power supply line PL is connected to the source (or drain) of the TFT 2 through a contact hole 90 formed through the interlayer insulating film 8, Furthermore, a planarizing insulating layer 92 made of a resin or the like is formed covering the interlayer insulating film 88, the data line DL, and the power supply line PL. The first electrode 200 is connected to the drain (or source) of the TFT 2 through a contact hole 94 formed through the planarizing insulating layer 92 and the interlayer insulating film 88.

As shown in FIGS. 1 and 2, the first electrode 200 also functions as the resonator spacer layer and is transparent and the lower reflective film 110 is formed below the first electrode 200, that is, the lower reflective film 110 is formed on the planarizing insulating layer 92 before the first electrode 200 is formed. In order to further improve reliability of connection between the TFT and the first electrode 200 at the contact hole 94, it is preferable that the lower reflective film 110 is not formed in the contact hole 94 as shown in FIGS. 1 and 2. It is possible to realize this configuration by using a mask having a pattern in which a region of the contact hole 94 is blocked, during the formation of the lower reflective film 110. However, as long as the contact can be reliably achieved, it is also possible to form the lower reflective film 110 also in the contact hole 94 and to form the first electrode 200 on the lower reflective film 110.

As shown in FIGS. 1 and 2, the surface of the first electrode 200 in the formation region of the contact hole 94 may be lower than the surface of the first electrode 200 in other regions. As described, in the present embodiment, it is important that the optical length L in the resonator is accurately set in order to determine the light emission wavelength (resonator wavelength) λ. Therefore, it is preferable to cover the region in which the surface is not flat, that is, the region above the contact hole 94 which tends to generate variation in the optical length L within a pixel, with the planarizing insulating layer 140 which covers around the ends of the first electrode 200.

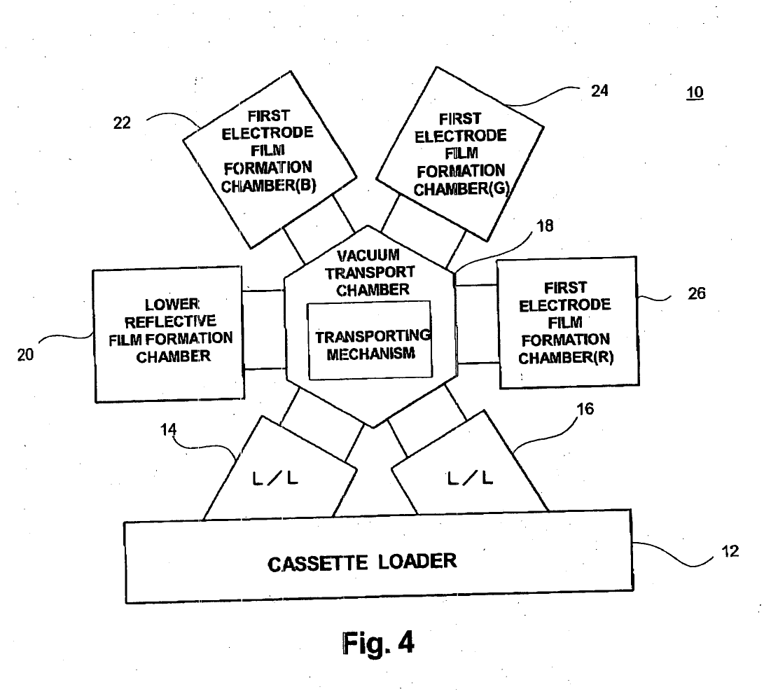

FIG. 4 shows a manufacturing apparatus for forming the active matrix organic EL display device as described above. This manufacturing apparatus is a film formation device 10 for forming the lower reflective film 110 and the conductive resonator spacer layer which also functions as the first electrode and having different thicknesses for each light emission wavelength, on a substrate to be processed to which the layers to the planarizing insulating layer 92 (refer to FIGS. 1 and 2) are formed. The film formation device 10 comprises a cassette loader 12, load lock chambers 14 and 16, a vacuum transport chamber 18, a lower reflective film formation chamber 20, and first electrode film formation chambers 22, 24, and 26 having different film formation thicknesses.

A cassette in which the substrate to be processed is stored in a state of vacuum and which is transported is connected at the cassette loader 12, and the substrate to be processed is transported to the load lock chamber 14. Also in the cassette loader 12, an exporting cassette is connected, which transports the substrate for which the film formation processes at the film formation device 10 are completed to the cassette while maintaining a state of vacuum.

When air in the load lock chamber 14 is discharged and the load lock chamber 14 reaches a predetermined degree of vacuum, the gate is opened, the substrate to be processed is received from the cassette loader 12, the gate between the load lock chamber 14 and the cassette loader 12 is closed, and the s to be processed is sent to the vacuum transport chamber 18. The vacuum transport chamber 18 comprises a transporting mechanism of the substrate such as a robot arm and executes transporting processes of the substrate to be processed into and out of the lower reflective film formation chamber 20 and into and out of the first electrode film formation chambers 22, 24, and 26 while maintaining the inside of the chamber at vacuum.

The substrate to be processed which is transported from the load lock chamber 14 to the vacuum transport chamber 18 is first sent to the lower reflective film formation chamber 20. As described above, the lower reflective film 110 shown in FIGS. 1 and 2 must have a high reflectivity. When the lower reflective film 110 is to be filled in the contact hole 94, it is necessary for the lower reflective film 110 and the active layer of the TFT 2 to be capable of being electrically connected, and a metal material such as, for example, Ag, Au, Pt, and Al or an alloy thereof is used.

As a method of forming a film, it is possible to employ vacuum evaporation, sputtering, etc. A mask having openings corresponding to the pixel regions is aligned by a mask alignment mechanism provided within the chamber on a side of a surface to which the films are to be formed of the substrate to be processed which is transported into the lower reflective film formation chamber 20. A metal material from a vacuum evaporation source, for example, is layered on the substrate to be processed corresponding to the opening pattern of the mask and a lower reflective film 110 having a pattern for each pixel region is formed on the surface of the substrate to be processed (surface of the planarizing insulating layer 92) simultaneously with the film formation.

After the lower reflective film 110 is formed, the substrate to be processed is transported to the vacuum transport chamber 18. More specifically, while a state of vacuum is maintained, that is, after the lower reflective film is formed, the material source is removed from the atmosphere of the film formation chamber 20 and, after the lower reflective film formation chamber 20 becomes a predetermined vacuum level, the gate between the lower reflective film formation chamber 20 and the vacuum transport chamber 18 is opened and the substrate to be processed is transported by the transporting mechanism of the vacuum transport chamber 18 to the vacuum transporting chamber 18 which is maintained at a state of vacuum. Then, the gate at the boundary between the lower reflective film formation chamber 20 and the vacuum transport chamber 18 is closed. One of the gates between the vacuum transport chamber 18 and the first electrode formation chambers 22, 24, and,26 is then opened and the substrate to be processed is transported from the vacuum transport chamber 18 through the opened gate into the film formation chamber of one of the first electrode film formation chambers 22, 24, and 26 which is maintained at a predetermined level of vacuum. As the first electrode 200, a transparent conductive metal oxide material such as ITO and IZO is used and is layered, for example, through sputtering.

In the present embodiment, masks in which openings are selectively opened at corresponding pixel positions of the first electrode to be formed as the resonator space layer which is determined based on the light emission wavelength are provided in the film formation chambers 22, 24, and 26, The mask is aligned with the substrate to be processed which is transported, on the side of the surface to which the film is to be formed, and a film is formed to form the first electrode 200 at a predetermined position with a predetermined thickness.

The order of formation of films in the film formation chambers 22, 24, and 26, that is, an order of formation of the first electrodes 200 may be an order of increasing thickness or an order of decreasing thickness. In the present embodiment, the mask is aligned on the substrate to be processed on the side of a surface to which the film is to be formed and the first electrode 200 having an individual pattern for each pixel is formed. It is preferable to form the film in the order from a thinner thickness to a thicker thickness in order to reduce the possibility of contact of the mask which is aligned at a position close to the film formation surface with the first electrode 200 which is already formed, which result in damages on the surface.

The thickness of the first electrode 200 must be increased as the wavelength becomes longer, based on the equation (1). Thus, the thicknesses for the pixels satisfy the relationship: (thickness of pixel for R light)>(thickness of pixel for G light)>(thickness of pixel for B light). Thus, in the present embodiment, if the first electrode film formation chamber 22 is a first electrode film formation chamber for pixels of B light, the film formation chamber 24 is a first electrode film formation chamber for pixels of G light, and the film formation chamber 26 is a first electrode film formation chamber for pixels of R light, a film formation process of the first electrode 200 (B) for pixels of B light at the film formation chamber 22, a film formation process of the first electrode 200 (G) for pixels of G light at the film formation chamber 24, and the film formation process of the first electrode 200 (R) for pixels of R light at the film formation chamber 26 are executed in this order for the substrate to be processed. The film formation procedures in the first electrode film formation chambers 22, 24, and 26 are identical to each other. Exemplifying the film formation chamber 22, a gate is opened while the chamber is maintained in a vacuum state, the substrate to be processed is transported by the transporting mechanism from the vacuum transport chamber 18, the gate is closed after the transporting mechanism is evacuated from the film formation chamber 22, and the mask which is made of a metal or a semiconductor material is aligned with the substrate to be processed by the mask alignment mechanism. After the alignment, the first electrode 200 for pixels of B light is formed on a position on the substrate corresponding to the pixels of B light covering the lower reflective film 110 of the substrate to be processed, through, for example, sputtering. After the film is formed, air in the film formation chamber is evacuated, the material source is removed from the atmosphere, the gate between the film formation chamber 22 and the vacuum transport chamber 18 is opened, the substrate to be processed, on which the first electrode 200 for pixels of B light is formed, is transported to the vacuum transport chamber 18, and the gate is again closed.

In the film formation chambers 24 and 26, a first electrode 200 having a thickness corresponding to the pixels of G light and a first electrode 200 having a thickness corresponding to the pixels of R light are formed through similar processes. After all first electrodes 200 for pixels of R, G, and B are formed, the substrate to be processed is transported from the vacuum transport chamber 18 to the load lock chamber 16 while a state of vacuum is maintained and is sent to the next layering step, that is, the layering device of the organic light emitting element layer 120, through the cassette loader 12.

As described, with the structure of the film formation device as shown in FIG. 4, after the lower reflective film 110 is formed the substrate to be processed is transported to the first electrode film formation chambers 22, 24, and 26 without being exposed to the atmosphere and the first electrodes 200 are formed in the film formation chambers 22, 24, and 26. Therefore, no natural oxide film or the like is formed on a surface of the lower reflective film 116 and the surface of the lower reflective layer is maintained in a clean state. Therefore, there is no reduction in the reflectivity, a high degree, of contact can be obtained between the lower reflective layer and the first electrode 200 made of ITO or the like, and the reliability and lifetime as a display device can be improved.

Although the first electrodes 200 are formed for each of pixels of R, G, and B, it is possible to pattern the electrode simultaneously with the film formation by using masks when the first electrodes 200 are formed, and, as a consequence, it is possible to change the optical length L of the resonator for each emitted light while minimizing increase in the number of manufacturing steps. The thickness of the first electrode 200 can be accurately and easily controlled by, for example, changing the film formation periods in the film formation chambers 22, 24, and 26.

In the above description, film formation with respect to one substrate to be processed has been described. Alternatively, it is also possible to employ a batch type manufacturing method in which a plurality of substrates to be processed are introduced into the film formation chamber and the processes are executed almost simultaneously.

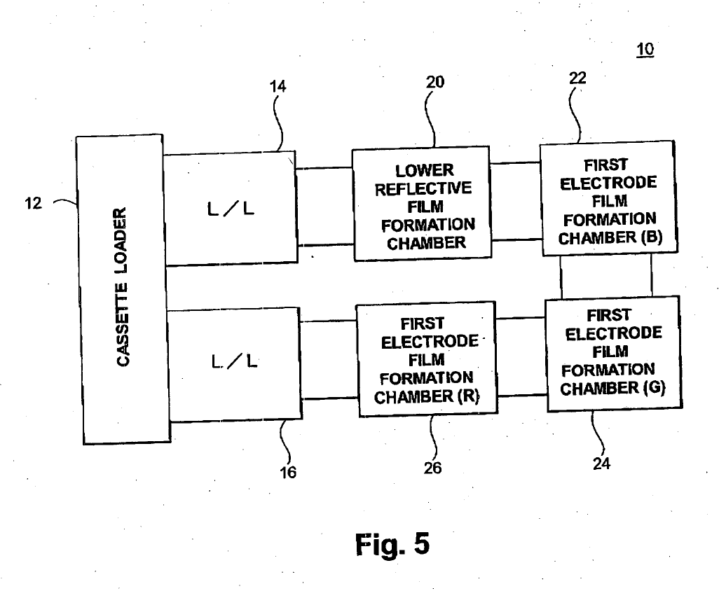

Although the film formation device of FIG. 4 has a structure in which all substrates to be processed are transported via the vacuum transport chamber 18 at the center to the next film formation chamber, it is also possible to employ an inline type film formation device in which the film formation chambers 20, 22, 24, and 26 are directly connected with gates therebetween in the order of the film formation process with respect to the substrate to be processed, as shown in FIG. 5. With the film formation device having a structure shown in FIG. 4, however, it is possible to more easily respond to a change in the manufacturing procedures such as a change in the order of film formation, compared to the structure of FIG. 5, In FIG. 4, the relative positions of the film formation chambers are arbitrary, but by providing the chambers, having corresponding film formation processes which are connected, near to each other, it is possible to efficiently move the transport mechanism, which contributes to shortening of the manufacturing time.

1. A display device comprising a plurality of pixels and which realizes a color display using emitted light of at least two wavelengths, wherein
each of the plurality of pixels comprises a microresonator structure formed between a lower reflective film formed on a side near a substrate and an upper reflective film formed above the lower reflective film with an organic light emitting element layer therebetween,
the lower reflective film is formed by a tansflective metal thin film,
a conductive resonator spacer layer which functions as an electrode for supplying charges to the organic light emitting element layer and having an individual pattern for each pixel is provided between the lower reflective film and the organic light emitting element layer, the conductive resonator spacer layer being a transparent conductive metal oxide layer and having a thickness which differs among pixels emitting light of different wavelengths, and
light obtained in the organic light emitting element layer is intensified by the microresonator structure formed between the lower reflective film and the upper reflective film and is emitted to the outside through the conductive resonator spacer layer and the lower reflective film.

2. A display device according to claim 1, wherein
emitted light from each pixel is one of red, blue, and green, and
the conductive resonator spacer layer is layered to different thicknesses for pixels of red, pixels of blue, and pixels of green.

3. A display device according to claim 1, wherein
the lower reflective film contains silver, gold, platinum, aluminum, or an alloy of any of these metals.

4. A display device comprising a plurality of pixels and which realizes a color display-using emitted light of at least two wavelengths, wherein
each of the plurality of pixels comprises a microresonator structure formed between a lower reflective film formed on a side near a substrate and a transflective upper reflective film formed above the lower reflective film with an organic light emitting element layer therebetween,
an optical length corresponding to a distance between the lower reflective film and the upper reflective film differs among pixels emitting light of different wavelengths, and
light which is intensified by the microresonator structure is emitted to the outside through the upper reflective film.

5. A display device according to claim 4, wherein
a conductive resonator spacer layer which functions as an electrode for supplying charges to the organic light emitting element layer and having an individual pattern for each pixel is provided between the lower reflective film and the upper reflective film, and
the conductive resonator spacer layer has a thickness which differs among pixels emitting light of different wavelengths.

6. A display device according to claim 5, wherein
the conductive resonator spacer layer is provided between the lower reflective film and the organic light emitting element layer and contains a conductive metal oxide.

7. A display device according to claim 4, wherein
the lower reflective film contains silver, gold, platinum, aluminum, or an alloy of any of these metals.

8. A manufacturing method of a display device which comprises a plurality of pixels and realizes a color display by emitted light of at least two wavelengths, and in which each pixel comprises a microresonator formed between a lower reflective film and an upper reflective film formed above the lower reflective film with an organic light emitting element layer therebetween, the organic light emitting element layer having at least one layer; and an optical length corresponding to a distance between the lower reflective film and the upper reflective film of the microresonator differs among pixels corresponding to light emission colors, wherein
the lower reflective film of each pixel is formed, and
a plurality of conductive resonator spacer layers having different thicknesses among pixels of different colors of emitted light are sequentially formed on the lower reflective film and continuous with the lower reflective film in different film formation chambers.

9. A manufacturing method of a display device according to claim 8, wherein
the conductive resonator spacer layer is an electrode layer which supplies charges to the organic light emitting element layer, and
the conductive resonator spacer layer is formed in each of the film formation chambers by layering a conductive metal oxide to a predetermined thickness in an individual pattern for each pixel using a mask.

10. A manufacturing method of a display device according to claim 8, wherein
emitted light from each pixel is one of red, blue, and green, and
the conductive resonator spacer layers are layered to different thicknesses for pixels of red, pixels of blue, and pixels of green.

11. A manufacturing method of a display device according to claim 8, wherein
the lower reflective film is a metal film containing silver, gold, platinum, aluminum, or an alloy of any of these metals, and
a transparent conductive metal oxide layer is formed as the conductive resonator spacer layer having a predetermined thickness sequentially after the metal film is formed.

12. An apparatus for manufacturing a display device in which each pixel comprises a microresonator formed between a lower reflective film and an upper reflective film formed above the lower reflective film with an organic light emitting element layer therebetween, an optical length corresponding to a distance between the lower reflective film and the upper reflective film of the microresonator differs among pixels corresponding to wavelengths of emitted light, and a color display is realized by emitted light of at least two wavelengths, the apparatus comprising:
a lower reflective film formation chamber in which the lower reflective film is formed; and
a spacer film formation chamber in which a conductive resonator spacer layer is layered, the conductive resonator spacer layer being formed between the lower reflective film and the organic light emitting element layer for adjusting the optical length of the microresonator based on light emission wavelength of light emitted from the pixel, wherein
a plurality of the spacer film formation chambers are provided corresponding to thicknesses of the conductive resonator spacer layer to be formed; and
the lower reflective film formation chamber and the plurality of the spacer film formation chambers are connected to each other directly or through a transport chamber so that a substrate to be processed can be transported while a state of vacuum is maintained.

13. A manufacturing apparatus of a display device according to claim 12, wherein
in the spacer film formation chamber, the conductive resonator spacer layer is formed on the lower reflective film in a vacuum atmosphere using a mask having an opening corresponding to a predetermined pixel region.

14. A manufacturing apparatus of a display device according to claim 12, wherein
the lower reflective film formation chamber is a film formation chamber in which a metal film containing silver, gold, platinum, aluminum, or an alloy of any of these metals is formed on the substrate to be processed, and
in the spacer film formation chamber, an oxide of indium or tin or an indium tin oxide is layered to a predetermined thickness as the conductive resonator spacer layer on the substrate to be processed which is transported while a state of vacuum is maintained and onto which the metal film is formed.
